(19) United States
(12) Patent Application Publication
(10) Pub. No.: US 2006/0256531 A1
(43) Pub. Date: Nov. 16, 2006

(54) Thermal solution with isolation layer

(75) Inventors: Ioan Sauciuc, Phoenix, AZ (US); Dustin P. Wood, Chandler, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/129,158

(22) Filed: May 13, 2005

(51) Int. Cl. H05K 7/20

(52) U.S. Cl. 361/705

(57) ABSTRACT

A thermal solution having a thermal energy transfer path and an isolation layer disposed on the thermal energy path is described herein.

### TECHNICAL FIELD

Embodiments of the present invention relate generally to the field of integrated circuits, and more particularly to a method and apparatus for maintaining effective thermal regulation of electrical components while still enabling selective voltage control over the component body.

### BACKGROUND

Elements of some electrical components tend to leak charge by gaining or losing electrons. It has been proposed to electrically bias the body of some components to inhibit or stop leakage. It may be necessary to provide thermal transfer to and from these components to regulate component temperature. Means to regulate temperature may be referred to as a thermal solution. The voltage potential of the thermal solution may need to be regulated to control electromagnetic interference (EMI) coming from it. It may become necessary to electrically bias a circuit component body to a first electrical potential and regulate a thermal solution to a second electrical potential. For the thermal solution to work effectively, it typically has to be in thermal transfer communication with the component. However, when a component body is biased to a first potential, and a thermal solution is held at a second potential a significant amount of current will flow from one to the other across the thermal transfer boundary, making effective reliable body biasing virtually impossible.

For example, in mobile computers biasing the CPU, or processor die, body may be desirable to minimize leakage to help preserve battery life. It may also be desirable to ground the thermal solution. The thermal solution may be in thermal transfer contact with the processor die via a thermal interface material or TIM. TIMs with effective heat transfer may have low electrical resistance. Effective body biasing and effective heat transfer is thus virtually impossible to maintain.

Thermal solutions include, but are not limited to: heat sinks; heat pipes; heat spreaders; heater blocks; thermal transfer plates; and vapor chambers. TIMs include but are not limited to thermally conductive greases, compounds, elastomers, and adhesive tapes.

The electrical component may be an integrated circuit which may have “hot spots” which are areas of concentrated heat flux emanating from them since an integrated circuit may have one or more areas of specialized function that become particularly busy depending on which tasks are performed.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a cross-sectional view taken along the line 1-1 in FIG. 2;

FIG. 2 illustrates a plan view in accordance with a first described embodiment of the present invention;

FIG. 3 illustrates a cross-sectional view in accordance with a second described embodiment of the present invention;

FIG. 4 illustrates a cross-sectional view in accordance with a third described embodiment of the present invention;

FIG. 5 illustrates a cross-sectional view in accordance with a fourth described embodiment of the present invention;

FIG. 6 illustrates a cross-sectional view in accordance with a fifth embodiment of the present invention;

FIG. 7 illustrates a cross-sectional view in accordance with a sixth described embodiment of the present invention;

FIG. 8 illustrates a cross-sectional view in accordance with a seventh described embodiment of the present invention;

FIG. 9 illustrates a cross-sectional view in accordance with an eighth described embodiment of the present invention;

FIG. 10 illustrates a cross-sectional view in accordance with a ninth described embodiment of the present invention;

FIG. 11 illustrates a cross-sectional view in accordance with a tenth described embodiment of the present invention;

FIG. 12 illustrates a cross-sectional view in accordance with an eleventh described embodiment of the present invention;

FIG. 13 is a block diagram illustrating a system including a thermal solution according to an embodiment of the present invention; and

FIG. 14a, 14b, and 14c are flow diagrams illustrating a method in accordance with an embodiment of the present invention.

### DETAILED DESCRIPTION OF ILLUSTRATIVE EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made in alternate embodiments. Therefore, the following detailed description is not to be taken in a limiting sense, and the scope of embodiments in accordance with the present invention is defined by the appended claims and their equivalents.

Embodiments of the present invention may be directed to a circuit component that may be an integrated circuit such as a microprocessor installed on a circuit which may be a printed circuit board such as a computer motherboard, having a device in thermal contact therewith. The device may be a thermal solution such as, but not limited to: a heat sink, heat pipe, heat spreader, heater block, thermal transfer plate, or vapor chamber. The thermal solution and circuit element may be in contact with one another via one or more contact locations that may include a thermal interface material (TIM) such as thermally conductive greases, compounds, elastomers, or adhesive tapes.

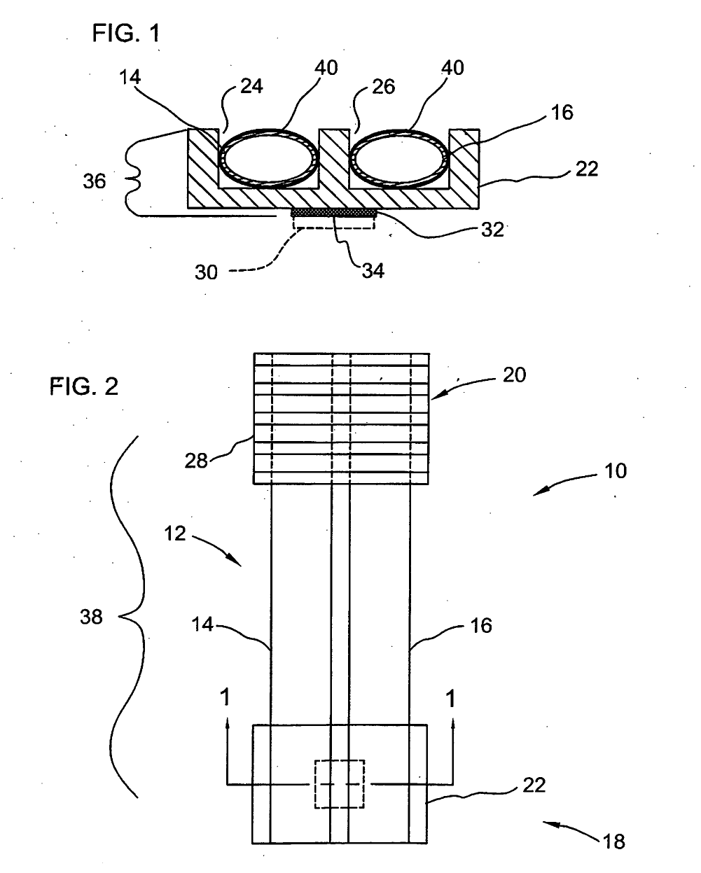

FIG. 1 is a cross-sectional view in accordance with a first described embodiment of the invention taken along the section line 1-1 in FIG. 2. FIG. 2 illustrates a plan view in accordance with the first described embodiment of the present invention. A thermal solution 10 which may be a heat pipe, having a heat pipe body 12 is made, in this case, from a first tube 14 and a second tube 16. Each tube 14, 16 has an evaporator end 18 and an opposite condenser end 20. A heater block 22 defines a first opening 24 and a second opening 26 which at least partially enclose the evaporator end 18 of the respective first tube 14 and second tube 16. The condenser end 20 of the first tube 14 and second tube 16 are connected to a remote heat exchanger 28. To illustrate how the thermal solution 10 may be utilized it is shown here positioned on a circuit element 30, which is shown here in dashed lines. The circuit element 30 may be, for example, an integrated circuit mounted onto an appropriate circuit substrate (not shown). A thermal interface material (TIM) 32 maintains thermal contact between the circuit element 30 and the heater block 22 transferring heat to the heater block and spreading the heat flux. The heat flux is further spread as it is conducted through the heater block 22 to the tubes 14, 16 of the evaporator end 18 of the heat pipe body 12. In this case, the TIM 32 and heater block 22 each define portions of a heat spreader layer 36. Further, the surface or surface area of the TIM 32 may be referred to as the thermal energy receiving surface 34. When included with the thermal solution 10, the heat pipe, works in a known way drawing heat from the evaporator end 18 to the condenser end 20 defining a thermal transfer path 38 from a thermal energy receiving surface 34 to a thermal energy discharging surface on the remote heat exchanger 28. An isolation layer 40 in the form of, e.g., a dielectric layer may be coated, or otherwise positioned on the evaporator end 18 of the tubes 14 and 16 allowing heat transfer from the thermal energy receiving surface 34 to the thermal energy discharging surface, and inhibiting electric current transfer along the thermal transfer path 38. Accordingly, isolation layer 40 is also referred to as electrical isolation layer. In this embodiment the isolation layer 40 is discontinuous and is on two tubes. Any one or greater number of tubes may be used. Other thermal solutions, not using a heat pipe, can also be used in alternate embodiments. More example embodiments follow.

The electrical component may be an integrated circuit, and the integrated circuit may have hot spots. The thickness and material selected for the spreading layer may be determined from the heat flux from the hot spots and the amount of spreading necessary to keep the heat flux on the isolation layer below a predetermined threshold. Alternatively, selection of the isolation layer material and thickness may be determined from the amount of spreading achieved by the spreading layer. They can also be used alone or in combination. For example, an air gap may be used, created, for example, by use of spacers or other known spacing techniques. Alternate embodiments may also be practiced with mixed dielectric layers, for example, air and silicon nitride. In some cases, for example using an air gap, the isolating layer may function as, at least part of, the thermal spreading layer.

The electrical isolation layer 40 may be made of a dielectric material and may be a thick high thermal conductivity dielectric material, for example, silicon nitride, or aluminum nitride, or it may be a very thin low thermal conductivity material, for example, glass, or polyimide. Other dielectric materials may also be used in alternate embodiments. The layer can be positioned along the thermal transfer path by any suitable means including, but not limited to, coating, soldering, adhesion brazing, or diffusion.

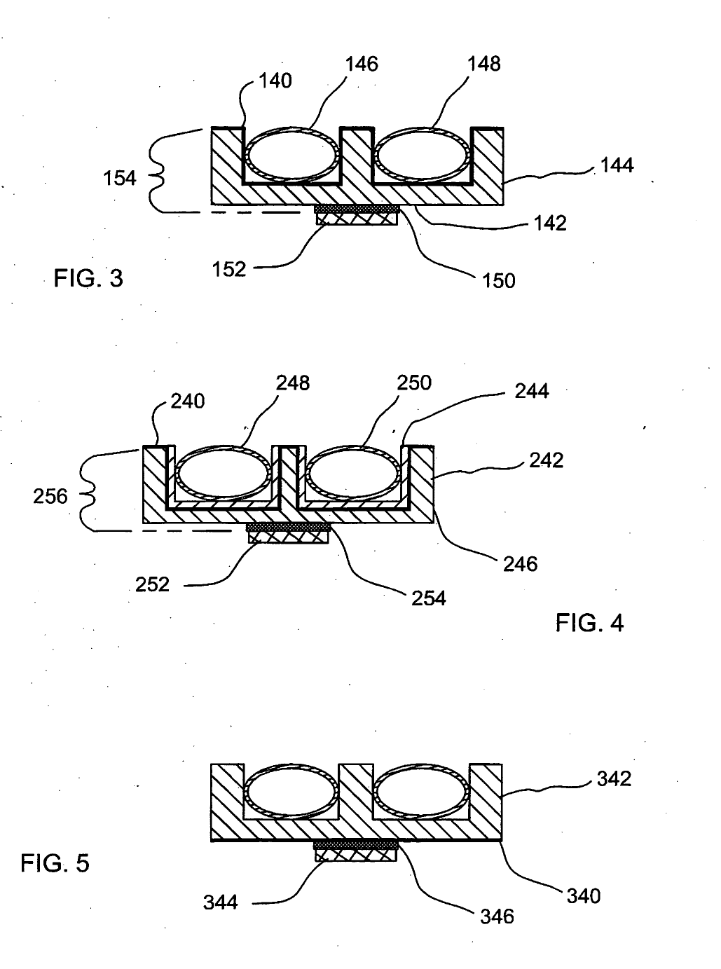

FIG. 3 illustrates a cross-sectional view in accordance with a second described embodiment of the present invention. In this example embodiment an electrical isolation layer 140, such as a dielectric layer, is positioned on a surface of a heater block 142 separating the heater block main body 144 from the evaporator ends of heat pipes 146 and 148. A TIM 150 may be interposed between a component 152 that may require heat removal and the heater block 142. The heater block main body 144 and the TIM 150 are each part of a heat spreader layer 154. The arrangement allows heat to pass from the component 152 to a thermal energy discharging surface (not shown) but impedes or prevents electrical current transfer. The electrical isolation layer 140 may be positioned and/or attached in place by any suitable means.

FIG. 4 illustrates a cross-sectional view in accordance with a third described embodiment of the present invention. In this example embodiment an electrical isolation layer 240, such as a dielectric layer, is sandwiched between an outer portion 242 and an inner portion 244 of the heater block separating the heater block main body 246 from the evaporator ends of the heat pipes 248 and 250. The arrangement allows heat to pass from the component 252 to the heat pipe evaporator tubes 248 and 250 but impedes or prevents any electrical current transfer. The electrical isolation layer 240 may be positioned and/or attached in place by any suitable means. A TIM layer 254 and the outer portion 242 define a heat spreader layer 256.

FIG. 5 illustrates a cross-sectional view in accordance with a fourth described embodiment of the present invention. In this example embodiment an electrical isolation layer 340, such as a dielectric layer, may be positioned or secured onto the bottom of a heater block main body 342. The arrangement allows heat to pass from a component 344 to the heater block main body 342 but impedes or prevents any current transfer. The layer 340 may be positioned and/or attached in place by any suitable means. A TIM layer 346 is adapted as a heat spreader layer to spread heat from the component 344.

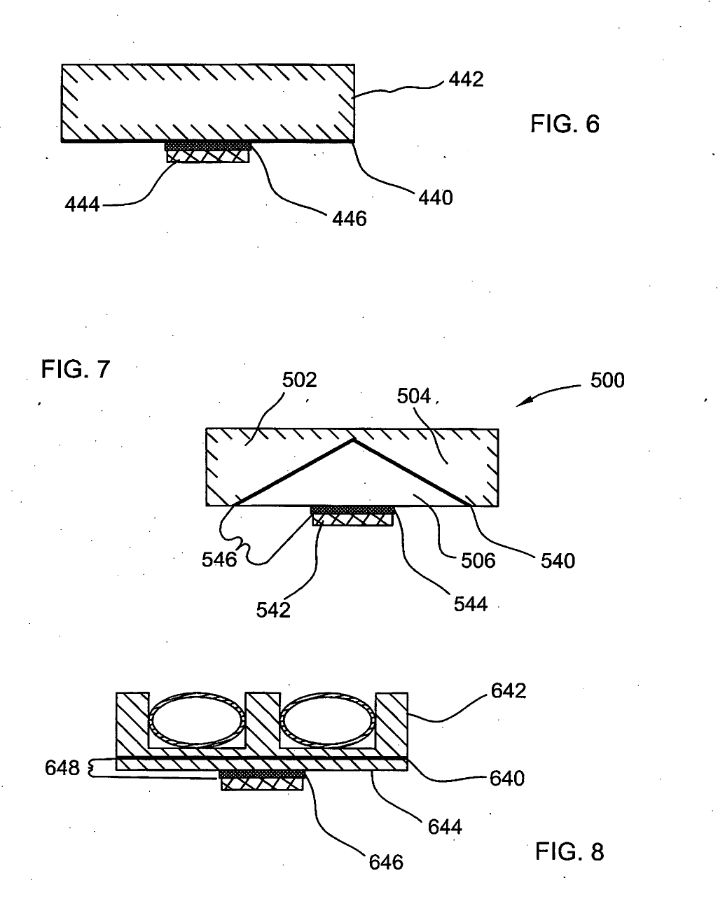

FIG. 6 illustrates a cross-sectional view in accordance with a fifth described embodiment of the present invention. In this example embodiment an electrical isolation layer 440, such as a dielectric layer, may be positioned or secured onto the bottom of a vapor chamber 442. The arrangement allows heat to pass from a component 444 to the vapor chamber 442 but impedes or prevents any current transfer. The layer 440 may be positioned and/or attached in place by any suitable means. A TIM layer 446 is adapted as a heat spreader to spread heat from the component 444.

FIG. 7 illustrates a cross-sectional view in accordance with a sixth described embodiment of the present invention. In this example embodiment a vapor chamber 500 defines a right evaporator 502 and a left evaporator 504 on either side of a parallelepiped block 506. An electrical isolation layer 540, such as a dielectric layer, may be positioned or secured dividing the parallelepiped block 506 from evaporators 502, 504. The arrangement allows heat to pass from a component 542 to the vapor chamber evaporators 502, 504 but impedes or prevents any electric current transfer. The layer 540 may be positioned and/or attached in place by any suitable means. A TIM layer 544 and the parallelepiped block 506 define a heat spreader layer 546.

FIG. 8 illustrates a cross-sectional view in accordance with a seventh described embodiment of the present invention. In this example embodiment an electrical isolation layer 640, such as a dielectric layer, is sandwiched between a spreader block body 642 and a bottom surface 644. A TIM layer 646 and the bottom surface 644 define a heat spreader layer 648.

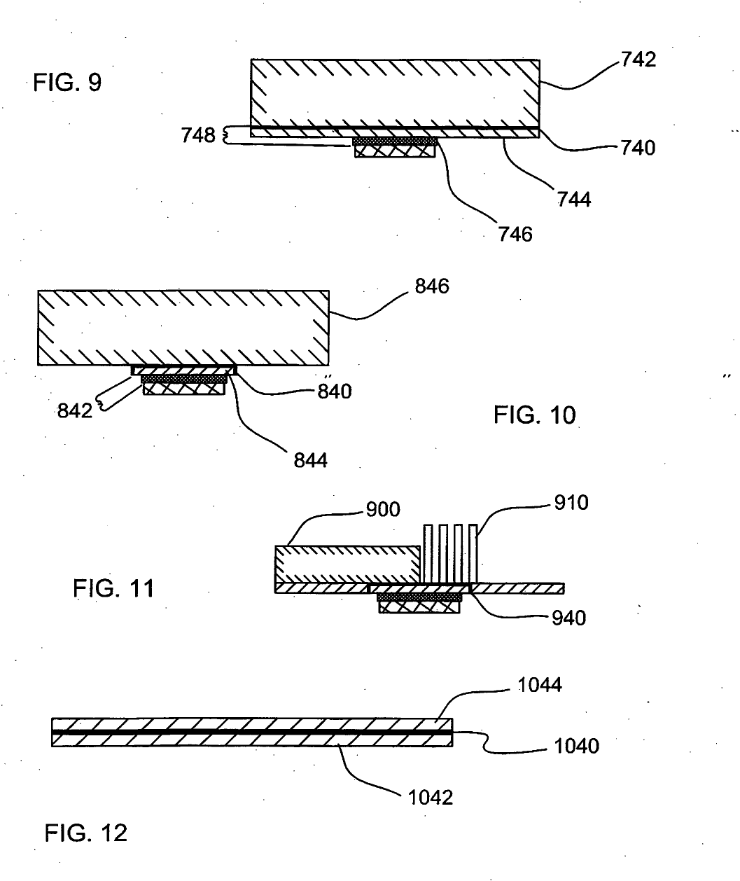

FIG. 9 illustrates a cross-sectional view in accordance with an eighth described embodiment of the present invention. In this example embodiment an electrical isolation layer 740, such as a dielectric layer, is sandwiched between a vapor chamber body 742 and a bottom surface 744. A TIM layer 746 and the bottom surface 744 define a spreader layer 748.

FIG. 10 illustrates a cross-sectional view in accordance with a ninth described embodiment of the present invention. In this example embodiment an isolation layer 840 partly surrounds a heat spreader layer 842 which includes a thermally conductive member 844. The isolation layer 840 allows heat to pass to the thermal solution 846 which may be a vapor chamber. The isolation layer 840 also inhibits electric current flow. In one embodiment, the isolation layer 840 is a dielectric layer.

FIG. 11 illustrates a cross-sectional view in accordance with a tenth described embodiment of the present invention in which more than one thermal removal element 900 and 910 are in thermal transfer contact with an isolation layer 940 arranged to allow thermal transfer, but impede electric transfer. In one embodiment, the isolation layer 940 is a dielectric layer.

FIG. 12 illustrates a cross-sectional view in accordance with a tenth described embodiment of the present invention. An isolation material 1040 such as, but not limited to, aluminum nitride, silicon nitride, glass, polyimide, or air is arranged between a spreader layer 1042 and a thermally conductive layer 1044. The isolation material 1040 also inhibits electric current flow across it. The arrangement is adapted to be positioned between an element requiring heat removal and any appropriate thermal energy discharge means.

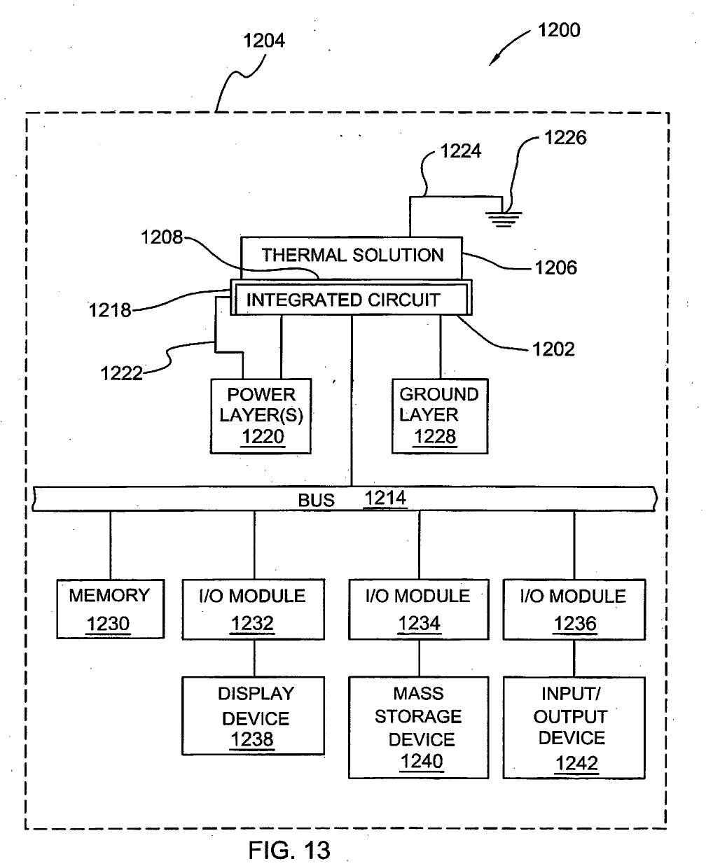

FIG. 13 illustrates a block diagram of a system 1200 which is just one of many possible systems in which one or more of the earlier described thermal solution embodiments may be used. The system 1200 may include one or more heat sinks as described herein. In this illustrated system 1200, an electrical component may be an integrated circuit 1202 which may be a processor. The integrated circuit 1202 may be directly coupled to a printed circuit board (PCB) 1204, represented here in dashed line, or indirectly coupled by way of a socket (not shown). The PCB 1204 may be a motherboard. A thermal solution 1206 may be in thermal transfer contact with an exposed surface 1208, for example, the top, of the integrated circuit 1202. The thermal solution 1206 may be one of the earlier described thermal solution embodiments, having an isolation layer that may be a dielectric layer that allows thermal transfer from a thermal receiving surface of the thermal solution to a thermal dissipation end of the thermal solution, but inhibits electric current flowing from the electrical component through the thermal solution.

The integrated circuit has a body 1218 which may be biased to a potential. The bias may be achieved by directly or indirectly electrically connecting the body 1218 to a power layer 1220 of the PCB 1204 as illustrated by line 1222. The body 1218 may also be biased to any selected potential by connecting it to a potential external to the PCB 1204. The thermal solution 1206 may be connected to a second potential. For example, it may be grounded as illustrated by a line 1224 connecting it to a ground 1226. The thermal solution 1206 may be connected to ground by other ways. For example, it may be connected to a ground layer 1228 of the PCB 1204. The integrated circuit 1202 may also be coupled to the power layer 1220 and the ground layer 1228 of the PCB 1204.

Additionally, system 1200 may include a main memory 1230 and one or more, for example three, input/output (I/O) modules 1232, 1234 and 1236. These elements including the earlier described integrated circuit 1202 may be coupled to each other via bus 1214. The system 1200 may further include a display device 1238, a mass storage device 1240 and an input/output (I/O) device 1242 coupled to the bus 1214 via respective input/output (I/O) modules 1232, 1234, and 1236. Examples of the memory include, but are not limited to, static random access memory (SRAM) and dynamic random access memory (DRAM). The memory may also include cache memory. Examples of the display device may include, but are not limited to, a liquid crystal display (LCD), cathode ray tube (CRT), light-emitting diode (LED), gas plasma, or other image projection technology. Examples of the mass storage device include, but are not limited to, a hard disk drive, a compact disk (CD) drive, a digital versatile disk (DVD) drive, a floppy diskette, a tape system, and so forth. Examples of the input/output devices may include, but are not limited to, devices which may be suitable for communication with a computer user, for example a keyboard, a mouse, a microphone, a voice recognition device, a display, a printer, speakers, and a scanner.

Various embodiments of the invention can also be used to thermally manage other components, for example, discrete components such as capacitors or resistors with imperfect body insulation, which may require heat removal but electrical isolation.

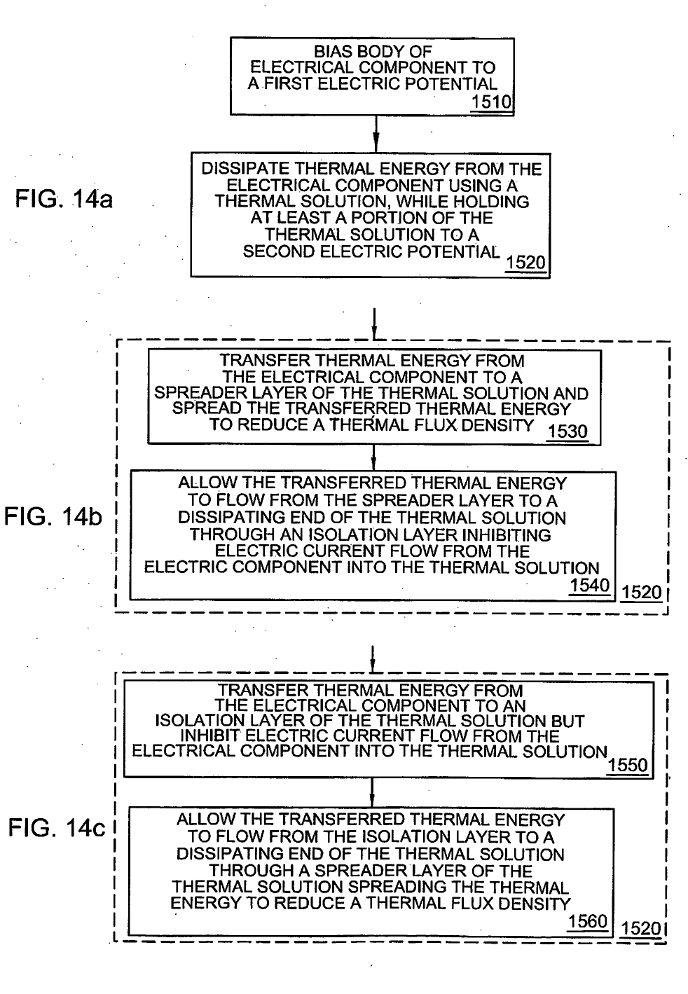

FIGS. 14a, 14b, and 14c are flow diagrams illustrating various methods in accordance with various embodiments of the present invention. The method includes: 1510, biasing a body of an electrical component to a first electric potential; and 1520, dissipating thermal energy from the electrical component using a thermal solution, while holding at least a portion of the thermal solution to a second electric potential.

In one embodiment, the 1520 operation includes:

1530, transferring thermal energy from the electrical component to a spreader layer of a thermal solution, and spreading the transferred thermal energy to reduce a thermal flux density; and
1540, allowing the transferred thermal energy to flow from the spreader layer to a dissipating end of the thermal solution, through an isolation layer inhibiting electric current flow from the electrical component into the thermal solution.
   In another embodiment, the 1520 operation includes:
1550, transferring thermal energy from the electrical component to an isolation layer of a thermal solution, but inhibiting electric current flow from the electrical component into the thermal solution; and
1560, allowing the transferred thermal energy to flow from the isolation layer to a dissipating end of the thermal solution, through a spreader layer of the thermal solution spreading the thermal energy to reduce a thermal flux density.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. A thermal solution comprising:
a thermal energy transfer path having a thermal energy receiving surface disposed at a first end, and a thermal energy discharging surface disposed at a second end; and
an isolation layer disposed on said thermal energy transfer path, before said second end, and adapted to allow transfer of thermal energy from said thermal energy receiving surface to said thermal energy discharging surface, but inhibiting electric current transfer along the thermal energy transfer path.

2. The thermal solution of claim 1, wherein the thermal energy receiving surface is adjacent to a circuit element adapted to be held at a first potential, and a portion of the thermal solution is disposed on a side of the isolation layer proximate to the thermal energy discharging surface and adapted to be held at a second potential.

3. The thermal solution of claim 2, wherein said second potential is a ground potential.

4. The thermal solution of claim 1, further comprising a spreader layer disposed on the thermal energy transfer path before the thermal energy discharging surface, to spread the thermal energy being transferred from the thermal energy receiving surface to the thermal energy discharging surface, and reduce thermal flux density.

5. The thermal solution of claim 4, wherein the spreader layer includes a thermally conductive material.

6. The thermal solution of claim 1, wherein the thermal solution further comprises a heat pipe and a heater block, and said isolation layer is a coated layer on an evaporator end of said heat pipe.

7. The thermal solution of claim 1, wherein said isolation layer comprises a dielectric material selected from the group consisting of silicon nitride, aluminum nitride, glass, polyimide, and air.

8. The thermal solution of claim 1, wherein the isolation layer is one selected from the group consisting of:
a dielectric layer coated on one or more heat pipes of the thermal solution;
a dielectric layer disposed on one or more heater block channels of the thermal solution;
a dielectric layer sandwiched between conductive layers of a heater block of the thermal solution;
a dielectric layer disposed on a surface of a heater block of the thermal solution proximal to a circuit element;
a dielectric layer disposed on a surface of a vapor chamber of the thermal solution proximal to a circuit element;
a dielectric layer disposed within a vapor chamber of the thermal solution, between a block and at least one evaporator of the vapor chamber;
a dielectric layer embedded within a heater block of the thermal solution;
a dielectric layer embedded within a vapor chamber of the thermal solution;
a dielectric layer partially surrounding a spreader layer of the thermal solution;
a dielectric layer disposed on a surface of one or more of thermal removal elements of the thermal solution proximal to a circuit element; and
a dielectric layer disposed between a substantially thin spreader layer and a substantially thin thermally conductive layer.

9. A method comprising:
biasing a body of an electrical component to a first electric potential; and
dissipating thermal energy from the electrical component using a thermal solution, while holding at least a portion of the thermal solution to a second electric potential, including allowing thermal energy to flow towards a thermal discharging surface of a thermal energy transfer path of the thermal solution, through an isolation layer of the thermal solution inhibiting electric current flow from the electrical component, the isolation layer being disposed on the thermal energy transfer path, before the thermal discharging surface.

10. The method of claim 9, further comprising spreading the thermal energy with a spreader layer disposed on the thermal energy transfer path, before the thermal discharging surface, to reduce thermal flux density.

11. The method of claim 10, wherein the spreading of the thermal energy is performed before the thermal energy flows through the isolation layer.

12. The method of claim 10, wherein the spreading of the thermal energy is performed after the thermal energy flows through the isolation layer.

13. The method of claim 9, wherein the isolation layer comprises a dielectric material chosen from the group consisting of silicon nitride, aluminum nitride, glass, air and polyimide.

14. The method of claim 9, wherein said biasing comprises coupling the body of the electrical component to a power source.

15. The method of claim 9, wherein said holding includes grounding the thermal solution.

16. A system comprising:
an integrated circuit having a body being biased to a potential and having an exposed surface;
a thermal solution in thermal transfer contact with said exposed surface of the integrated circuit to dissipate thermal energy of the integrated circuit, said thermal solution being grounded and having a thermal energy transfer path including a thermal energy receiving surface disposed at one end and a thermal energy dissipating surface disposed at another end, and an isolation layer disposed between the two ends inhibiting electric current flowing from the integrated circuit into the thermal solution; and
a mass storage device coupled to the integrated circuit.

17. The system of claim 16, wherein said isolation layer comprises a dielectric material selected from the group consisting of silicon nitride, aluminum nitride, glass, air, and polyimide.

18. The system of claim 16, wherein the isolation layer is selected from the group consisting of:
a dielectric layer coated on one or more heat pipes of the thermal solution;
a dielectric layer disposed on one or more heater block channels of the thermal solution;
a dielectric layer sandwiched between conductive layers of a heater block of the thermal solution;
a dielectric layer disposed on a surface of a heater block of the thermal solution proximal to the circuit element;
a dielectric layer disposed on a surface of a vapor chamber of the thermal solution proximal to the circuit element;
a dielectric layer disposed within a vapor chamber of the thermal solution, between a block and at least one evaporator of the vapor chamber;
a dielectric layer embedded within layers of a heater block of the thermal solution;
a dielectric layer embedded within layers of a vapor chamber of the thermal solution;
a dielectric layer partially surrounding a spreader layer of thermal solution;
a dielectric layer disposed on a surface of a one or more thermal removal elements of the thermal solution proximal to the integrated circuit; and
a dielectric layer disposed between a substantially thin spreader layer of the thermal solution and a substantially thin thermally conductive layer of the thermal solution.

19. The system of claim 16, wherein said thermal solution further comprises a spreader layer disposed between the thermal energy receiving surface and the thermal energy discharging surface of thermal energy transfer path to spread the thermal energy and reduce thermal flux density.
